(19) United States
(12) Patent Application Publication
(10) Pub. No.: US 2025/0131170 A1
(43) Pub. Date: Apr. 24, 2025

(54) METHOD FOR THE AUTOMATED GENERATION OF AN INDIVIDUAL HYDRAULIC COMPONENT CHARACTERISTIC MAP FOR AN INDIVIDUAL HYDRAULIC COMPONENT OF A HYDRAULIC COMPONENT TYPE

(71) Applicant: HAWE Hydraulik SE, Aschheim (DE)

(72) Inventors: Fabian Kreutmayr, Aschheim (DE); Markus Imlauer, Aschheim (DE)

(73) Assignee: HAWE Hydraulik SE, Aschheim (DE)

(21) Appl. No.: 18/922,937

(22) Filed: Oct. 22, 2024

(30) Foreign Application Priority Data
Oct. 23, 2023 (DE) 10 2023 210 438.5

(51) Int. Cl. G06F 30/28

(52) U.S. Cl. CPC G06F 30/28

(57) ABSTRACT

A method for automatically generating an individual hydraulic component characteristic map for an individual hydraulic component V1, V2 of a hydraulic component type uses an autoencoder, which is trained using a training data set for the hydraulic component type, and a reduced individual data set, which is generated for the individual hydraulic component V1, V2, in order to automatically generate the individual hydraulic component characteristic map, for example in the form of a lookup table.

### CROSS REFERENCE TO RELATED APPLICATION

This application claims the priority benefit German Patent Application No. 10 2023 210 438.5, filed on Oct. 23, 2023, the entire contents of which is incorporated herein by reference in its entirety.

### FIELD

The present disclosure relates to methods for automatically generating an individual hydraulic component characteristic map for an individual hydraulic component of a hydraulic component type.

### BACKGROUND

Various different types of hydraulic components are known, such as hydraulic valves or hydraulic pumps. These types of hydraulic components are configured to influence different parameters of a hydraulic system. For example, fluid parameters of a hydraulic fluid, such as a hydraulic oil, can be parameters of the relevant hydraulic system that are influenced by the respective hydraulic components. A fluid parameter is understood to be, for example, a pressure, a volume flow, a temperature, a flow rate, a density or any other parameter describing a property of the hydraulic fluid. Other parameters, such as a position of a valve piston of a hydraulic valve, a swivel angle of a variable displacement pump or a stroke of a piston rod of a hydraulic cylinder, can also represent parameters of such a hydraulic system. Control parameters, such as a control current for actuating an actuator of a hydraulic valve or a variable displacement pump, also represent parameters of a hydraulic system.

Therefore, it is an objective of the present disclosure to provide a simpler and more cost-effective way of generating an individual hydraulic component characteristic map for an individual hydraulic component of a hydraulic component type.

### SUMMARY

A method for automated generation of an individual hydraulic component characteristic map for an individual hydraulic component of a hydraulic component type is provided. In one embodiment, the method includes generating a training data set for the hydraulic component type, training an autoencoder using the training data set, automatically generating a reduced individual data set for the individual hydraulic component, and automatically generating the individual hydraulic component characteristic map for the individual hydraulic component using the trained autoencoder and the reduced individual data set.

The training data set may include a plurality of different hydraulic component characteristic maps of the same type, and creation of the training data set may include generating at least part of the training data set using a virtual simulation model of the hydraulic component type, and generating at least part of the training data set using real measurements on at least one individual training hydraulic component of the hydraulic component type.

In an embodiment, generating at least part of the training data set using the virtual simulation model includes generating the virtual simulation model of the hydraulic component type, identifying structural parameters of the hydraulic component type that have an influence on real behavior of the hydraulic component type due to series dispersion, defining limit values for identified structural parameters, whereby the limit values correspond to maximum real deviations due to series dispersion, generating a plurality of different virtual training models by randomized variation of the identified structural parameters of the virtual simulation model within the defined limits, and generating the plurality of different hydraulic component characteristic maps of the same type by simulating a defined test sequence on each virtual training model generated.

The reduced individual data set may include map data at least one defined measuring point. Automated generation of the reduced individual data set for the individual hydraulic component may includes automatically recording characteristic map data of the individual hydraulic component at the at least one defined measuring point during a final production test of the individual hydraulic component.

The individual hydraulic component may be a poppet valve and the individual hydraulic component characteristic map may be a valve characteristic map. The valve characteristic map maps a relationship between a control current of the poppet valve, a volume flow and a pressure difference across a control edge of the poppet valve.

The individual hydraulic component characteristic map may be configured as a lookup table.

A method for embedding an individual hydraulic component characteristic map of an individual hydraulic component may include generating a training data set for the hydraulic component type, training an autoencoder using the training data set, automatically generating a reduced individual data set for the individual hydraulic component, automatically generating the individual hydraulic component characteristic map for the individual hydraulic component using the trained autoencoder and the reduced individual data set, and embedding the individual hydraulic component characteristic map in a control unit assigned to the individual hydraulic component.

A method for controlling an individual hydraulic component may include generating a training data set for the hydraulic component type, training an autoencoder using the training data set, automatically generating a reduced individual data set for the individual hydraulic component, automatically generating the individual hydraulic component characteristic map for the individual hydraulic component using the trained autoencoder and the reduced individual data set, embedding the individual hydraulic component characteristic map in a control unit assigned to the individual hydraulic component, and controlling the individual hydraulic component using the individual hydraulic component characteristic map.

A hydraulic system is provided including an individual hydraulic component and a control unit. The control unit is associated with the individual hydraulic component and is configured to control the individual hydraulic component. An individual hydraulic component characteristic map for the individual hydraulic component may be generated by generating a training data set for the hydraulic component type, training an autoencoder using the training data set, automatically generating a reduced individual data set for the individual hydraulic component, and automatically generating the individual hydraulic component characteristic map for the individual hydraulic component using the trained autoencoder and the reduced individual data set. The individual hydraulic component characteristic map for the individual hydraulic component generated may be embedded in the control unit.

The control unit may be integrated into the individual hydraulic component.

The individual hydraulic component may be a hydraulic valve and the individual hydraulic component characteristic map may be an individual valve characteristic map which maps a relationship between a control current of the hydraulic valve, a volume flow and a pressure difference across a control edge of the hydraulic valve. The hydraulic valve may be a poppet valve or a pilot-operated poppet valve.

The hydraulic system may further include at least one pressure sensor for determining a current pressure difference across a control edge of the individual hydraulic valve, where the control unit applies a control current to the individual hydraulic valve on a basis of the individual valve characteristic map, the current pressure difference and a predetermined volume flow.

BRIEF DESCRIPTION

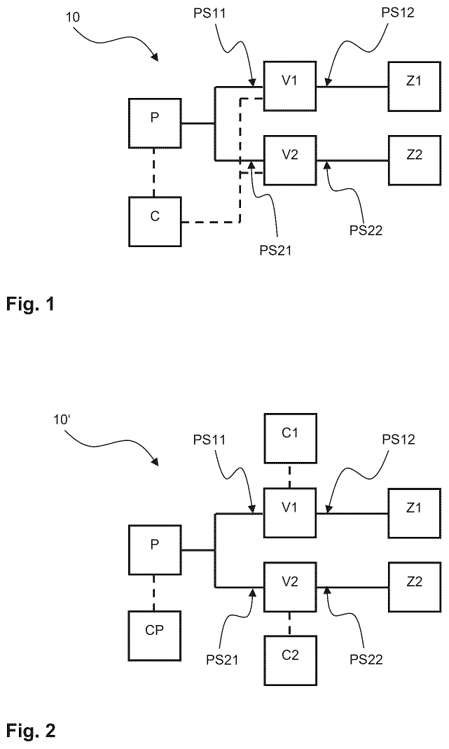

FIG. 1 depicts a hydraulic system with several individual hydraulic components and a control unit according to a first embodiment of the present disclosure;

FIG. 2 depicts a hydraulic system with several individual hydraulic components and several control units according to a second embodiment of the present disclosure;

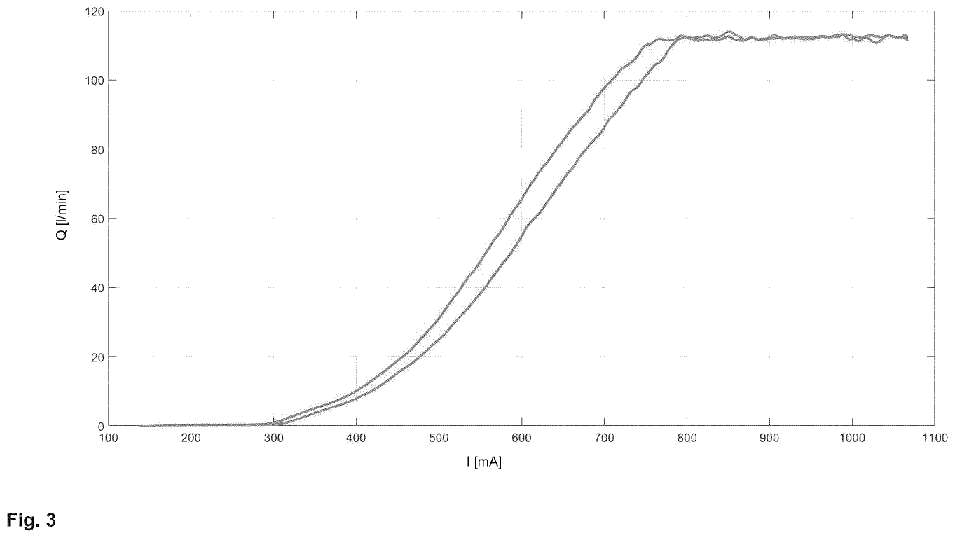

FIG. 3 depicts a diagram of an exemplary valve characteristic curve;

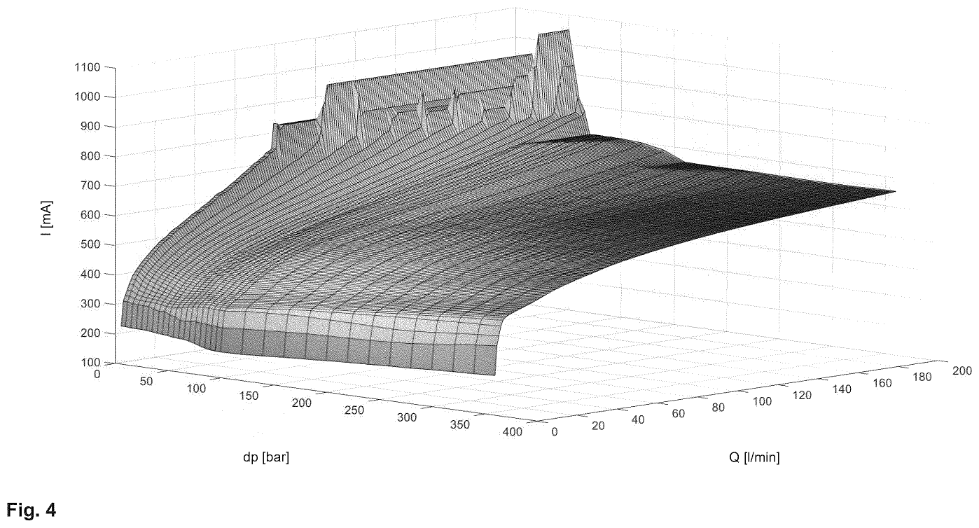

FIG. 4 depicts an exemplary individual valve characteristic map in the form of a lookup table for an individual hydraulic valve; and

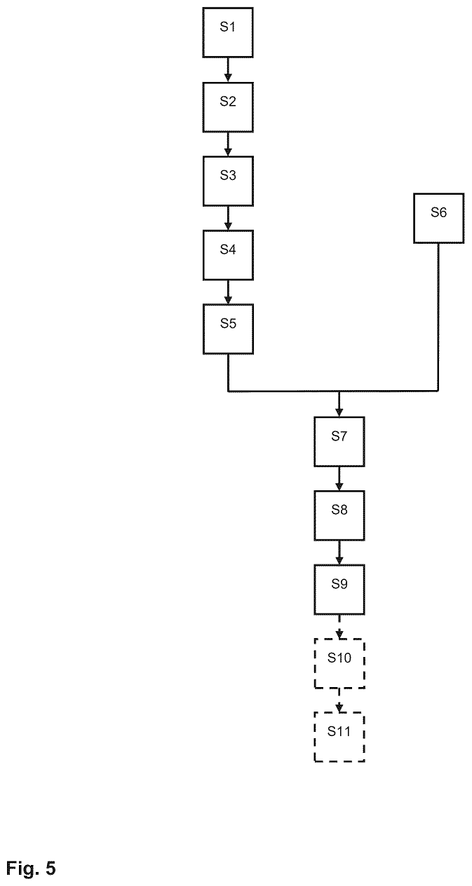

FIG. 5 depicts a flow chart illustrating a method according to the present disclosure.

### DETAILED DESCRIPTION

It is generally known to relate various parameters of a hydraulic system that are related to a specific hydraulic component type to each other via a hydraulic component characteristic map in order to characterize the specific behavior of the hydraulic component type in question in more detail. A hydraulic component characteristic map is any structure that establishes a functional relationship between at least two parameters of a hydraulic system. For example, a hydraulic component characteristic map can be a lookup table, a function or a collection of different hydraulic component characteristic curves of the same type in the form of a characteristic curve map. Such a hydraulic component characteristic map can then be embedded in a control unit that uses the hydraulic component characteristic map to control an individual hydraulic component of the hydraulic component type.

The basic behavior and the basic dynamics of the individual hydraulic components of a hydraulic component type are similar. However, due to the manufacturing process, all individual hydraulic components of a hydraulic component type differ slightly from each other structurally due to series variations. Each individual hydraulic component of the same hydraulic component type is therefore a unique hydraulic component due to the manufacturing process. These production-related structural deviations or this uniqueness of each individual hydraulic component means that the actual behavior of each individual hydraulic component deviates slightly from the actual behavior of another individual hydraulic component of the same hydraulic component type and therefore also from the ideal behavior. Accordingly, depending on the requirement profile, a general hydraulic component characteristic map that has been created for a hydraulic component type may not be accurate enough to control each individual, i.e. production-related unique, hydraulic component of the hydraulic component type precisely enough. In this case, each individual hydraulic component of a hydraulic component type must be completely measured with a relatively high resolution in order to correctly determine the respective individual hydraulic component characteristic map of the individual hydraulic component.

One example of a hydraulic system parameter that is regularly relevant for the control of hydraulic systems is the volume flow. The volume flows in a hydraulic system are mainly influenced by hydraulic valves. However, measuring volume flows is cost-intensive in practice and the corresponding sensor technology is susceptible to faults. However, for certain applications, such as extending a piston rod of a hydraulic cylinder at a defined speed, precise knowledge of the currently flowing volume flow is required. The currently flowing volume flow is directly related to the opening of the individual hydraulic valve and the pressure difference applied across the individual hydraulic valve. While the applied pressure difference can usually be recorded easily and reliably, this does not necessarily apply to the actual opening of the individual hydraulic valve, for example with pilot-operated poppet valves. Nevertheless, in order to be able to set volume flows as required via a control unit of the hydraulic system assigned to the individual hydraulic valve, it is possible to measure the individual hydraulic valve completely. In a test sequence, the applied current I of the individual hydraulic valve is slowly increased and lowered again after reaching the maximum. The pressure difference dp across the control edge of the individual hydraulic valve is kept constant. In addition, the resulting volume flow Q is measured. This results in a Q(I) characteristic curve for the measured individual hydraulic valve at the constant pressure difference dp. If this is repeated for a larger number of pressure differences dp, a collection of Q(I) characteristic curves for the individual hydraulic valve is created. This results in an individual valve characteristic map that describes the relationship Q=f(I,dp) (with I as current, dp as pressure difference, Q as volume flow and f as function) for the individual hydraulic valve. By inverting this function, a lookup table can be generated as an individual hydraulic component characteristic map that describes the relationship I=f (Q,dp). The individual hydraulic component characteristic map in the form of a lookup table, a given requested volume flow Q and the currently measured pressure difference dp can thus be used to determine the current I that must be applied to the individual hydraulic valve in order to obtain the requested volume flow Q. However, due to the production-related structural deviations between all individual hydraulic valves of the same hydraulic valve type described above, a complete measurement with a sufficiently high resolution of each individual hydraulic valve would have to be carried out in order to generate an individual hydraulic component characteristic map that enables sufficiently precise control of the volume flow. In practice, this is usually too time-consuming to be economically viable.

The solution to the problem is initially achieved with a method for the automated generation of an individual hydraulic component characteristic map for an individual hydraulic component of a hydraulic component type, the method comprising the following steps:
creating a training data set for the hydraulic component type,
training an autoencoder using the training data set,
automatically generating a reduced individual data set for the individual hydraulic component, and
Automatically generating the individual hydraulic component characteristic map for the individual hydraulic component based on the trained autoencoder and the reduced individual data set.

An “individual hydraulic component” is understood to be a unique hydraulic component of a specific hydraulic component type due to the manufacturing process. An “individual hydraulic component characteristic map” is therefore a production-related unique map of such an individual hydraulic component. An individual hydraulic component characteristic map can be in the form of a lookup table, a function or a collection of different hydraulic component characteristic maps of the same type in the form of a map. Preferably, the individual hydraulic component characteristic map is a lookup table.

An autoencoder is an artificial neural network. The autoencoder is used to learn a compressed representation of the training dataset on the basis of the training dataset, whereby in particular the meaningful features of the training dataset are extracted. Non-linear correlations can also be identified. In the linear case, an autoencoder is comparable to principal component analysis. An autoencoder consists of an encoder and a decoder. The encoder learns an encoding from the training data set and the decoder learns to reconstruct the training data set from the encoding. If the training data set is large enough, the autoencoder consequently also learns production-related structural deviations in individual hydraulic components of a hydraulic component type and can therefore generate a precise individual hydraulic component characteristic map for each individual hydraulic component based solely on the reduced individual data set. Thanks to the trained autoencoder and the reduced individual data set, the relevant production-related structural deviations are taken into account during the automated generation of the individual hydraulic component characteristic map via the autoencoder. As a result, it is no longer necessary to completely measure each individual hydraulic component in order to generate its individual hydraulic component characteristic map. Compared to the previously necessary complete measurement of each individual hydraulic component, this represents a considerably simpler and more cost-effective way of generating an individual hydraulic component characteristic map.

Preferably, the training data set comprises several different hydraulic component characteristic maps of the same type, in particular in the form of lookup tables. In addition, the generation of the training data set comprises the following:
generating at least part of the training data set using a virtual simulation model of the hydraulic component type, and/or
generating at least part of the training data set using real measurements on at least one individual training hydraulic component, preferably several individual training hydraulic components, of the hydraulic component type.

The larger the training data set is based on different hydraulic component characteristic maps of the same type, the more accurate the compressed representation of the hydraulic component type learned by the autoencoder becomes. The training data set can be generated either purely on the basis of a virtual simulation model or purely on the basis of real measurement data, i.e. complete measurements of individual training hydraulic components, or a mixture of virtual simulation data and real measurement data.

Preferably, generating at least part of the training dataset using a virtual simulation model comprises the following:
creating a virtual simulation model of the hydraulic component type,
identifying of structural parameters of the hydraulic component type, which have an influence on the real behavior of the hydraulic component type due to series dispersion,
defining limit values for the identified structural parameters, whereby the limit values correspond in particular to maximum real deviations due to series scattering,
generating several different virtual training models by randomized variation of the identified structural parameters of the virtual simulation model within the defined limit values, and
generating several different hydraulic component characteristic maps of the same type by simulating a defined test sequence on each virtual training model created.

The limit values for the identified structural parameters represent manufacturing tolerances, for example. By identifying and simulatively varying structural parameters of the hydraulic component type, which have an influence on the real behavior of the hydraulic component type due to series variation, series variations in individual hydraulic components can be simulated. This makes it possible to generate a realistic training data set for training the autoencoder without necessarily having to carry out complex series of measurements in high resolution on real individual hydraulic components. However, such a simulatively generated training data set can be supplemented or verified by existing real measurement data or completely replaced by existing real measurement data.

Preferably, the reduced individual data set includes characteristic map data at least one defined measuring point. Furthermore, the automated generation of the reduced individual data set for the individual hydraulic component comprises the following:
automatically recording the characteristic map data of the individual hydraulic component at the at least one defined measuring point during a final production test of the individual hydraulic component.

The reduced individual data set therefore comprises a subset of the individual hydraulic component characteristic map to be generated. Preferably, the reduced individual data set comprises characteristic map data at several defined measuring points. In general, a final production test is carried out during the production of each individual hydraulic component, in which the intended function of each individual hydraulic component produced is automatically checked for quality control reasons, for example. Since such a final production test is carried out anyway, one or more well-defined measuring points can be approached during the final production test and the desired characteristic map data recorded, which form the reduced individual data set, without much additional effort. Using the reduced individual data set, the decoder of the trained autoencoder can then generate the individual hydraulic component characteristic map, preferably a lookup table, in a simple and cost-effective manner.

Preferably, the individual hydraulic component is a hydraulic valve or a hydraulic pump. Accordingly, the individual hydraulic component characteristic map is a valve characteristic map or a pump characteristic map, in particular in the form of a lookup table.

The method described can therefore be used to generate individual hydraulic component characteristic maps for individual hydraulic components of different types of known hydraulic components in a simple and cost-effective manner.

The hydraulic valve is preferably a poppet valve, in particular a pilot-controlled poppet valve. The valve characteristic map, in particular in the form of a lookup table, maps a relationship between a control current of the poppet valve, a volume flow and a pressure difference across a control edge of the poppet valve.

With poppet valves, especially pilot operated poppet valves, it is often particularly difficult to determine the actual flow rate via the poppet valve. At the same time, production-related structural deviations in each individual poppet valve have a particularly large influence on the actual volume flow through the individual poppet valve. Accordingly, the method described is particularly suitable for the simple and cost-effective generation of individual valve characteristic maps, especially in the form of lookup tables, for individual poppet valves.

Furthermore, the solution to the problem is achieved with a method for embedding an individual hydraulic component characteristic map of an individual hydraulic component, which comprises the following steps:
generating the individual hydraulic component characteristic map according to the method described above for automatically generating an individual hydraulic component characteristic map for an individual hydraulic component of a hydraulic component type, and
embedding the individual hydraulic component characteristic map in a control unit assigned to the individual hydraulic component.

Furthermore, the solution to the problem is achieved with a method for controlling an individual hydraulic component, which comprises the following steps:
embedding an individual hydraulic component characteristic map of the individual hydraulic component according to the method described above for embedding an individual hydraulic component characteristic map of an individual hydraulic component, and
controlling the individual hydraulic component based on the individual hydraulic component characteristic map.

Furthermore, the solution to the problem is achieved with a hydraulic system with an individual hydraulic component and a control unit, wherein the control unit is assigned to the individual hydraulic component and is configured to control the individual hydraulic component, wherein an individual hydraulic component characteristic map for the individual hydraulic component, which was generated according to the method described above for the automated generation of an individual hydraulic component characteristic map for an individual hydraulic component of a hydraulic component type, is embedded in the control unit. In particular, the control unit controls the individual hydraulic component using the individual hydraulic component characteristic map, which is in particular a lookup table.

With the hydraulic system, precise individual control of the individual hydraulic components can be realized easily and cost-effectively via the individual hydraulic component characteristic map.

In the hydraulic system described, the control unit is preferably integrated into the individual hydraulic component. This means that the individual hydraulic component characteristic map can not only be generated during production of the individual hydraulic component, but can also be embedded directly in the integrated control unit during production. Alternatively, the individual hydraulic component characteristic map can also be subsequently embedded in the control unit assigned to the individual hydraulic component, for example by downloading it from the Internet. It is also conceivable that an individual hydraulic component characteristic map embedded in a control unit assigned to the individual hydraulic component is updated after a certain time, for example to map the change in the individual hydraulic component characteristic map over time. A change in the individual hydraulic component characteristic map can, for example, be mapped using the completed switching cycles.

Preferably, the individual hydraulic component is a hydraulic valve, preferably a poppet valve, more preferably a pilot-controlled poppet valve, and the individual hydraulic component characteristic map is an individual valve characteristic map which, in particular in the form of a lookup table, maps a relationship between a control current of the hydraulic valve, a volume flow and a pressure difference across a control edge of the hydraulic valve.

Preferably, the hydraulic system described also comprises at least one pressure sensor for determining a current pressure difference across a control edge of the individual hydraulic valve. The control unit applies a control current to the individual hydraulic valve based on the individual valve characteristic map, the current pressure difference and a predefined volume flow.

Production-related structural deviations in hydraulic valves often have a particular influence on the actual volume flow via the individual hydraulic valve. Consequently, it is particularly preferable to generate an individual valve characteristic map with reference to a volume flow via an individual hydraulic valve, to embed it in the control unit and to use this individual valve characteristic map in combination with a specified desired volume flow and the current pressure difference across the individual hydraulic valve to determine the control current with which the control unit must actuate the individual hydraulic valve in order to achieve the desired volume flow. This provides a simple and cost-effective way of precisely controlling the volume flow in a hydraulic system via an individual hydraulic valve.

FIG. 1 shows a hydraulic system 10 according to a first embodiment of the present disclosure.

The hydraulic system 10 comprises a first hydraulic valve V1 and a second hydraulic valve V2, which are two individual hydraulic components of the same hydraulic valve type. This means that although the individual first hydraulic valve V1 and the individual second hydraulic valve V2 are of the same hydraulic valve type, they are each unique due to production-related structural deviations (series variation). In the present case, the individual first hydraulic valve V1 and the individual second hydraulic valve V2 are each a pilot-operated poppet valve. In other words, the hydraulic component type of the individual first hydraulic valve V1 and the second hydraulic valve V2 is a pilot operated poppet valve.

The hydraulic system 10 further comprises a control unit C, a hydraulic pump P, which in this exemplary embodiment is configured as a variable displacement pump, a first hydraulic cylinder device Z1, a second hydraulic cylinder device Z2, a first pressure sensor PS11, a second pressure sensor PS 12, a third pressure sensor PS21 and a fourth pressure sensor PS22.

As shown schematically in FIG. 1 by solid connecting lines, the hydraulic pump P delivers a hydraulic fluid for actuating the first hydraulic cylinder device Z1 and the second hydraulic cylinder device Z2. The first hydraulic valve V1 and the individual second hydraulic valve V2 are each disposed in the flow path from the hydraulic pump P to the first hydraulic cylinder device Z1 and to the second hydraulic cylinder device Z2, respectively, in order to control the actuation of the hydraulic cylinder devices Z1 and Z2.

The control unit C of the hydraulic system 10 in FIG. 1 is a central control unit C, which is assigned to the hydraulic pump P, the first hydraulic valve V1 and the second hydraulic valve V2 in order to control them.

FIG. 2 shows a hydraulic system 10′ according to a second embodiment. The hydraulic system 10′ differs from the hydraulic system 10 according to the first embodiment in FIG. 1 only in that it comprises a first valve control unit C1, a second valve control unit C2 and a pump control unit CP. The first valve control unit C1 is assigned to the first hydraulic valve V1, the second valve control unit C2 is assigned to the second hydraulic valve V2 and the pump control unit CP is assigned to the hydraulic pump P. In particular, the first valve control unit C1 can be integrated into the individual first hydraulic valve V1, so that the individual first hydraulic valve V1 and the first valve control unit C1 form an integral component, for example in the form of a valve cartridge. In particular, the second valve control unit C2 can be integrated into the individual second hydraulic valve V2, so that the second hydraulic valve V2 and the second valve control unit C2 form an integral component, for example in the form of a valve cartridge. The pump control unit CP can also be integrated into the hydraulic pump P. The first valve control unit C1, the second valve control unit C2 and the pump control unit CP can be connected to each other for mutual data transmission directly or via a higher-level control unit of the hydraulic system 10′ (not shown), if this is necessary or desired.

Further components of the hydraulic system 10 in FIG. 1 and also of the hydraulic system 10′ in FIG. 2, such as LS lines, a hydraulic reservoir and return lines to the hydraulic reservoir or further hydraulic valves, are not shown here for the sake of simplicity. In general, it will be clear to those skilled in the field of hydraulics that the illustrations of the hydraulic system 10 in FIG. 1 and the hydraulic system 10′ in FIG. 2 are exemplary schematic representations, and that other combinations of individual hydraulic components of a hydraulic component type, such as hydraulic valves, hydraulic pumps and/or hydraulic cylinder devices, are possible to form hydraulic systems to which the present disclosure is also applicable.

To avoid repetition, the hydraulic system 10 from FIG. 1 is essentially described below and only the differences between the hydraulic system 10 from FIG. 1 and the hydraulic system 10′ from FIG. 2 are discussed. The corresponding descriptions of the hydraulic system 10 from FIG. 1 therefore also refer to the hydraulic system 10′ from FIG. 2.

The first pressure sensor PS11 and the second pressure sensor PS12 are assigned to the first hydraulic valve V1 in order to detect a current pressure difference across the individual first hydraulic valve V1. The third pressure sensor PS21 and the fourth pressure sensor PS22 are assigned to the second hydraulic valve V2 in order to detect a pressure difference across the individual second hydraulic valve V2. In the hydraulic system 10, the pressure sensors PS11 to PS22 are also connected to the control unit C for data transmission, although this is not shown in FIG. 1 for the sake of simplicity. In the hydraulic system 10′, for example, the first pressure sensor PS11 and the second pressure sensor PS12 are connected to the first valve control unit C1 for data transmission and the third pressure sensor PS21 and the fourth pressure sensor PS22 are connected to the second valve control unit C2 for data transmission, although this is not shown in FIG. 2 for the sake of simplicity.

If, for example, the output pressure of the hydraulic pump P is detected, it may also be sufficient to provide only the second pressure sensor PS12 and the fourth pressure sensor PS22 in the hydraulic systems 10, 10′ in order to detect the current pressure difference across the individual first hydraulic valve V1 and the individual second hydraulic valve V2, respectively.

A piston rod of the first hydraulic cylinder device Z1 is to be extended at a defined speed. For this purpose, the volume flow flowing via the individual first hydraulic valve V1 must be precisely controlled. This takes place via a defined opening of the individual first hydraulic valve V1. For this purpose, a defined control current is applied to the individual first hydraulic valve V1 by the control unit C in order to open the individual first hydraulic valve V1. Furthermore, a piston rod of the second hydraulic cylinder device Z2 is to be extended at a defined speed. For this purpose, the flow rate flowing via the individual second hydraulic valve V2 must be precisely controlled. This takes place via a defined opening of the second hydraulic valve V2. For this purpose, the individual second hydraulic valve V2 is subjected to a defined control current by the control unit C in order to open the individual second hydraulic valve V2.

The control unit C of the first embodiment is therefore assigned to the individual hydraulic valves V1, V2 and is configured to control the individual hydraulic valves V1, V2. For this purpose, a first individual valve characteristic map for the individual first hydraulic valve V1 and a second individual valve characteristic map for the individual second hydraulic valve V2 are embedded in the control unit C. The first individual valve characteristic map and the second individual valve characteristic map differ from each other and have each been generated according to a method described below for the automated generation of an individual hydraulic component characteristic map for an individual hydraulic component of a hydraulic component type.

First, with reference to FIG. 3 and FIG. 4, an individual valve characteristic map of an individual hydraulic valve is described as an example.

FIG. 3 shows a diagram in which the volume flow Q is plotted against the control current I. The diagram also shows an example of a Q(I) characteristic curve of an individual hydraulic valve, such as the individual first hydraulic valve V1 or the individual second hydraulic valve V2. It can be clearly seen here that as the control current I increases, the respective valve opens further and further and the flow rate Q increases accordingly until the respective valve is fully open and the flow rate levels off at its maximum. It can then be seen that the control current I is reduced again. The individual hydraulic valve closes accordingly and the volume flow Q finally drops back to zero. Such a Q(I) characteristic curve for an individual hydraulic valve is recorded in a quasi-static state, i.e. with a slow increase and decrease of the control current I. The pressure difference dp across the individual hydraulic valve is kept constant during the entire test sequence. The hysteresis of the measured individual hydraulic valve can be seen in FIG. 3. When the control current I is increased, the volume flow Q increases later (upward path, right section of the curve in FIG. 3), when the control current I is reduced, the volume flow Q decreases later (downward path, left section of the curve in FIG. 3). To generate a lookup table, as shown in FIG. 4 as an example, these hysteresis Q(I) curves are averaged. Depending on how pronounced the hysteresis effect is for the hydraulic valve type in question and how high the requirements are for the precision of the control of an individual hydraulic valve of the hydraulic valve type in question, hysteresis compensation can be carried out in a separate step using directional differentiation.

FIG. 4 in turn shows an exemplary graphical representation of an individual lookup table (individual hydraulic component characteristic map) for the individual first hydraulic valve V1. The lookup table in FIG. 4 illustrates the relationship between the volume flow Q and the control current I for various current pressure differences dp. With the lookup table in FIG. 4, it is possible to determine the control current I that must be applied to the individual first hydraulic valve V1 in order to obtain the desired flow rate Q for a current pressure difference dp and a specified desired flow rate Q. As can be seen in FIG. 4, the lookup table is a collection of discrete data points that represent the relationship I=f(Q,dp). Interpolation between the individual data points makes it possible to generate continuous signals for the control current I without jumps.

The basis for the lookup table in FIG. 4 is a larger number of Q(I) characteristic curves for the individual first hydraulic valve V1, which have been recorded at different constant pressure differences dp. If, for example, pressure differences dp in a range from 0 to 300 bar are to be mapped in steps or with a resolution of 10 bar, a characteristic curve map with 30 Q(I) characteristic curves forms the basis for a lookup table, as shown in FIG. 4. The characteristic curve map with the 30 Q(I) characteristic curves maps the relationship Q=f(I, dp). By inverting it, a lookup table like the one in FIG. 4 can be generated that maps the relationship I=f(Q, dp). Previously, to create such an individual lookup table for an individual hydraulic valve, the individual hydraulic valve in question had to be completely measured thirty times in order to generate the 30 Q(I) characteristic curves.

The method described below with reference to FIG. 5 for the automated generation of an individual hydraulic component characteristic map of an individual hydraulic component of a hydraulic component type makes this time-consuming measurement of each individual hydraulic component superfluous. The method is described by way of example using the individual first hydraulic valve V1, but can be applied analogously to the individual second hydraulic valve V2 or any other individual hydraulic component of a hydraulic component type.

In step S1, a virtual simulation model of the valve type of the individual first hydraulic valve V1 is generated, i.e. a virtual simulation model of an ideal pilot-controlled poppet valve of the hydraulic component type.

In step S2, structural parameters of the pilot-controlled poppet valve are identified that have an influence on the real behavior of the pilot-controlled poppet valve due to series dispersion.

In step S3, limit values are defined for the identified structural parameters. The defined limit values correspond to maximum real deviations due to series variation. In particular, the limit values correspond to manufacturing tolerances of the pilot operated poppet valve.

In step S4, several different virtual training models are generated by randomized variation of the identified structural parameters of the virtual simulation model within the defined limits.

In step S5, several different valve characteristics of the same type are generated in the form of lookup tables by simulating a defined test sequence on each virtual training model generated. This results in several different Q(I) characteristics for each virtual training model generated at several defined pressure differences dp. These Q(I) curves are averaged in order to obtain a clear correlation between the volume flow Q, the control current I and the pressure difference dp, i.e. to determine the hysteresis effects. The several different Q(I) curves are then inverted in order to obtain an individual lookup table for each virtual training model generated. In this way, an individual lookup table is generated for each virtual training model created.

Consequently, in steps S1 to S5, at least part of a training data set is generated using the virtual simulation model of the pilot-controlled poppet valve. In particular, several different individual lookup tables, such as those in FIG. 4, are simulatively generated in steps S1 to S5 in order to be used as part of the training data set.

Alternatively or additionally, at least part of the training data set is generated in step S6 using real measurements on at least one individual training hydraulic valve of the pilot operated poppet valve type. In step S6, several individual pilot-operated poppet valves are completely measured in order to generate several individual lookup tables such as those in FIG. 4. These individual lookup tables are used as part of the training data set.

The training data set thus comprises several different lookup tables of the same type, some of which have been generated simulatively on individual virtual training models of the pilot-controlled poppet valve and some of which have been generated by complete or partial measurement of individual training hydraulic valves.

In step S7, an autoencoder is trained using the training data set generated in this way. An encoder of the autoencoder receives the training data set, i.e. the several different lookup tables of the same type, as input and learns an encoding on this basis. A decoder of the autoencoder then learns to reconstruct the training data set from the encoding. In this way, the autoencoder learns a compressed representation of the training data set.

In step S8, a reduced individual data set is automatically generated for the individual first hydraulic valve V1. In the present case, several well-defined measuring points are approached during a final production test of the individual first hydraulic valve V1 and corresponding characteristic map data of the individual valve characteristic map to be generated is recorded. In particular, the resulting volume flow Q is measured for several defined pressure differences dp across the control edge of the individual first hydraulic valve V1 and several defined currents I of the individual first hydraulic valve V1. The discrete data points obtained in this way from control current I, volume flow Q and pressure difference dp form the reduced individual data set of the individual first hydraulic valve V1, which is automatically generated during the final production test of the individual first hydraulic valve V1.

In step S9, the individual valve characteristic map (see FIG. 4) for the individual first hydraulic valve V1 is automatically generated using the trained autoencoder (step S7) and the reduced individual data set (step S8). More precisely, the decoder of the autoencoder generates the complete lookup table from FIG. 4 using the reduced individual data set.

The method according to steps S1 to S9 can be applied in a simple and cost-effective manner to many other individual pilot-operated poppet valves, such as the individual second hydraulic valve V2. In this way, the trained autoencoder and automatically generated reduced individual data sets can be used to generate individual valve characteristic maps for further individual pilot-controlled poppet valves in a simple and cost-effective manner.

Finally, in step S10, the individual valve characteristic map of the individual first hydraulic valve V1 is embedded in the control unit C of the hydraulic system 10 or in the first valve control unit C1 of the hydraulic system 10′. Embedding in the control unit C, C1 assigned to the individual first hydraulic valve V1 can take place directly during production, for example if the individual first hydraulic valve V1 is configured as a valve cartridge with integrated first valve control unit C1, or subsequently, for example by downloading into the central control unit C of the hydraulic system 10 as shown in FIG. 1.

In step S11, the respective control unit C or C1 controls the individual first hydraulic valve V1 using the individual valve characteristic map.

In the present case, the control unit C applies a control current I to the individual first hydraulic valve V1 in order to set the desired volume flow Q via the individual first hydraulic valve V1. The control current I is determined by the control unit C using the individual valve characteristic map of the individual first hydraulic valve V1 in combination with the current pressure difference across the individual first hydraulic valve V1 measured by the pressure sensors PS11 and PS12 and the desired volume flow Q.

The control of the individual second hydraulic valve V2 by the control unit C, C2 assigned to it using the individual valve characteristic map of the individual second hydraulic valve V2 is carried out analogously. The description of the control of the individual first hydraulic valve V1 applies accordingly to the control of the individual second hydraulic valve V2.

It is also conceivable that steps S1 to S9 are repeated after a defined number of switching cycles in order to “adapt” the individual hydraulic component characteristic map after the defined number of switching cycles has been completed or to update the individual hydraulic component characteristic map. In other words, the method according to the disclosure not only makes it possible to map the series dispersion, but also an ageing or change in the individual hydraulic component characteristic map over time. The generation of a reduced individual data set for an individual hydraulic component (step S8), such as the individual first hydraulic valve V1, takes place independently of the manufacturing process of the individual hydraulic component. Thus, step S8 can in principle also be carried out (repeatedly) after the individual hydraulic component in question has already been in use, for example in order to map ageing processes or to apply the method according to the disclosure to individual hydraulic components that have already been produced.

1. A method for automated generation of an individual hydraulic component characteristic map for an individual hydraulic component of a hydraulic component type, the method comprising:
generating a training data set for the hydraulic component type,
training an autoencoder using the training data set,
automatically generating a reduced individual data set for the individual hydraulic component, and
automatically generating the individual hydraulic component characteristic map for the individual hydraulic component using the trained autoencoder and the reduced individual data set.

2. The method according to claim 1, wherein the training data set comprises a plurality of different hydraulic component characteristic maps of the same type, and creation of the training data set includes:
generating at least part of the training data set using a virtual simulation model of the hydraulic component type, and
generating at least part of the training data set using real measurements on at least one individual training hydraulic component of the hydraulic component type.

3. The method according to claim 2, wherein generating at least part of the training data set using the virtual simulation model comprises:
generating the virtual simulation model of the hydraulic component type,
identifying structural parameters of the hydraulic component type that have an influence on real behavior of the hydraulic component type due to series dispersion,
defining limit values for identified structural parameters, whereby the limit values correspond to maximum real deviations due to series dispersion,
generating a plurality of different virtual training models by randomized variation of the identified structural parameters of the virtual simulation model within the defined limits, and
generating the plurality of different hydraulic component characteristic maps of the same type by simulating a defined test sequence on each virtual training model generated.

4. The method according to claim 1, wherein the reduced individual data set comprises map data at least one defined measuring point, and
automated generation of the reduced individual data set for the individual hydraulic component comprises:
automatically recording characteristic map data of the individual hydraulic component at the at least one defined measuring point during a final production test of the individual hydraulic component.

5. The method according to claim 1, wherein the individual hydraulic component is a poppet valve and the individual hydraulic component characteristic map is a valve characteristic map, the valve characteristic map mapping a relationship between a control current of the poppet valve, a volume flow and a pressure difference across a control edge of the poppet valve.

6. The method according to claim 1, wherein the individual hydraulic component characteristic map is configured as a lookup table.

7. A method for embedding an individual hydraulic component characteristic map of an individual hydraulic component, comprising:
generating a training data set for the hydraulic component type,
training an autoencoder using the training data set,
automatically generating a reduced individual data set for the individual hydraulic component,
automatically generating the individual hydraulic component characteristic map for the individual hydraulic component using the trained autoencoder and the reduced individual data set, and
embedding the individual hydraulic component characteristic map in a control unit assigned to the individual hydraulic component.

8. A method for controlling an individual hydraulic component, comprising:
generating a training data set for the hydraulic component type,
training an autoencoder using the training data set,
automatically generating a reduced individual data set for the individual hydraulic component,
automatically generating the individual hydraulic component characteristic map for the individual hydraulic component using the trained autoencoder and the reduced individual data set,
embedding the individual hydraulic component characteristic map in a control unit assigned to the individual hydraulic component, and
controlling the individual hydraulic component using the individual hydraulic component characteristic map.

9. A hydraulic system comprising an individual hydraulic component and a control unit, wherein the control unit is associated with the individual hydraulic component and is configured to control the individual hydraulic component, wherein an individual hydraulic component characteristic map for the individual hydraulic component is generated by generating a training data set for the hydraulic component type, training an autoencoder using the training data set, automatically generating a reduced individual data set for the individual hydraulic component, and automatically generating the individual hydraulic component characteristic map for the individual hydraulic component using the trained autoencoder and the reduced individual data set, wherein the individual hydraulic component characteristic map for the individual hydraulic component generated is embedded in the control unit.

10. The hydraulic system according to claim 9, wherein the control unit is integrated into the individual hydraulic component.

11. The hydraulic system according to claim 9, wherein the individual hydraulic component is a hydraulic valve and the individual hydraulic component characteristic map is an individual valve characteristic map which maps a relationship between a control current of the hydraulic valve, a volume flow and a pressure difference across a control edge of the hydraulic valve.

12. The hydraulic system according to claim 11, wherein the hydraulic valve is a poppet valve.

13. The hydraulic system according to claim 11, wherein the hydraulic valve is a pilot-operated poppet valve.

14. The hydraulic system according to claim 11, wherein the hydraulic system further comprises at least one pressure sensor for determining a current pressure difference across a control edge of the individual hydraulic valve,
wherein the control unit applies a control current to the individual hydraulic valve on a basis of the individual valve characteristic map, the current pressure difference and a predetermined volume flow.
